(19) United States
(12) Patent Application Publication
(10) Pub. No.: US 2010/0037820 A1
(43) Pub. Date: Feb. 18, 2010

(54) Vapor Deposition Reactor

(75) Inventor: Sang In LEE, Sunnyvale, CA (US)

Correspondence Address: FENWICK & WEST LLP, SILICON VALLEY CENTER, 801 CALIFORNIA STREET, MOUNTAIN VIEW, CA, 94041, US

(73) Assignee: SYNOS TECHNOLOGY, INC., Sunnyvale, CA (US)

(21) Appl. No.: 12/539,490

(22) Filed: Aug. 11, 2009

Related U.S. Application Data
(60) Provisional application No. 61/088,677, filed on Aug. 13, 2008.

(51) Int. Cl. C23C 16/455

(52) U.S. Cl. 118/719

(57) ABSTRACT

A vapor deposition reactor includes a reaction module includes a first injection unit for injecting a first material onto a substrate. At least one second injection unit is placed within the first injection unit for injecting a second material onto the substrate. The substrate passes the reaction module through a relative motion between the substrate and the reaction module. The vapor deposition reactor advantageously injects a plurality of materials onto the substrate while the substrate passes the reaction module without exposing the substrate to the atmosphere in a chamber.

### CROSS-REFERENCE TO RELATED APPLICATION

This application claims priority to under 35 U.S.C. §119(e) to co-pending U.S. Provisional Patent Application No. 61/088,677, filed on Aug. 13, 2008, which is incorporated by reference herein in its entirety.

### BACKGROUND

1. Field of Art

This invention relates to a vapor deposition reactor for forming a thin film on a substrate.

2. Description of the Related Art

Semiconductor materials include silicon-based semiconductors such as Si and SiGe, metal oxide semiconductors such as ZnO, group III-V compound semiconductors such as GaAs, GaP, GaN, AlGaAs and InP; and group II-VI compound semiconductors such as CdSe, CdTe, ZnS and CdHgTe. Semiconductor devices are manufactured using these as substrate material, forming metal films or insulating films on the substrate material, and carrying out photolithography, etching, cleaning and thin film deposition.

When fabricating a metal-oxide-semiconductor field-effect transistor (MOSFET) that is widely used in highly integrated circuits, an insulating film is formed on a semiconductor substrate. The insulating film is used as the gate insulating film for the transistor. Then, a metal film is formed on the substrate so that voltage or current required for driving the device can be applied. The reaction between the substrate and the metal film or the insulating film is important. In some cases, even a slight reaction may change of properties of semiconductor device. Therefore, a precise interface control is required to fabricate properly functioning semiconductor devices.

Deposition techniques are gradually shifting from chemical vapor deposition (CVD) such as low-pressure CVD (LPCVD) performed in a furnace toward atomic layer deposition (ALD). ALD consists of the following four stages: (i) injecting a source precursor, (ii) removal of a physical adsorption layer, (iii) injection of a reactant precursor, and (iv) removal of a physical adsorption layer.

FIG. 1 is a flowchart illustrating ALD process according to a conventional technique. Referring to FIG. 1, ALD process may include: loading a substrate (S11), passing the substrate by a source precursor injection module to inject a source precursor (S12), passing the substrate by a purge/pumping module to remove a physical adsorption layer from the source precursor (S13), passing the substrate by a reactant precursor supply module to inject a reactant precursor (S14), and passing the substrate by a purge/pumping module to remove a physical adsorption layer from the reactant precursor (S15). The above steps may be repeated until a layer with desired final thickness is obtained (S16). To perform these steps, an expensive valve that sequentially supplies the source precursor, purge gas, reactant precursor, and a purge gas to the substrate is needed.

Because the source precursor is deposited on the semiconductor substrate after removing natural oxide films from the semiconductor substrate using HF or other chemical substances, the source precursor comes in direct contact with the semiconductor substrate. While the source precursor remains in contact with the substrate, mutual diffusion or formation of unwanted interface may occur on the surface of the semiconductor substrate due to the reaction between the substrate and the source precursor. In case the semiconductor device has a sufficiently large design rule, such phenomena has minimal effect on the properties of the semiconductor device. However, if the design rule is about 32 nm or smaller, as in nano devices or quantum devices, the reactions at the interface or the unwanted formation of interface may become relevant.

### SUMMARY

Embodiments provide a vapor deposition reactor capable of injecting a plurality of different materials to a substrate passing a reaction module using a plurality of injection units. The reaction module of the vapor deposition reactor is configured so that one injection unit is placed within another injection unit.

In one embodiment, a vapor deposition reactor includes a reaction module. The reaction module includes a first injection unit for injecting a first material onto a substrate, and at least one second injection unit placed within the first injection unit for injecting a second material onto the substrate. The substrate passes the reaction module through a relative motion between the substrate and the reaction module.

### BRIEF DESCRIPTION OF THE DRAWINGS

FIG. 1 is a flowchart illustrating atomic layer deposition (ALD) process, according to a conventional process.

FIG. 2 is a schematic perspective view of a vapor deposition reactor, according to one embodiment.

FIG. 3A is a cross-sectional view of a vapor deposition reactor, according to one embodiment;

FIG. 3B is a partially enlarged view of the vapor deposition reactor of FIG. 3A, according to one embodiment.

FIGS. 3C and 3D are cross-sectional views of a reaction module of a vapor deposition reactor according to embodiments.

FIG. 3E is a cross-sectional view of a vapor deposition reactor according to another embodiment.

FIG. 4A is a side cross-sectional view of a first injection unit of a vapor deposition reactor, according to one embodiment.

FIGS. 4B to 4F are bottom views of a reaction module of a vapor deposition reactor, according to embodiments.

FIG. 5A is a cross-sectional view of a reaction module of a deposition reactor, according to another embodiment.

FIG. 5B is a bottom view of the reaction module of FIG. 5A, according to one embodiment.

FIG. 6A is a cross-sectional view of a reaction module of a vapor deposition reactor, according to one embodiment.

FIG. 6B is a bottom view of the reaction module of FIG. 6A, according to one embodiment.

FIGS. 7A and 7B are bottom views of a reaction module of a vapor deposition reactor, according to embodiments.

FIG. 8 is a cross-sectional view of a reaction module of a vapor deposition reactor, according to another embodiment.

FIGS. 9A and 9B are cross-sectional views of a reaction module of a vapor deposition reactor, according to other embodiments.

FIG. 10 is a cross-sectional view of a reaction module of a vapor deposition reactor, according to another embodiment.

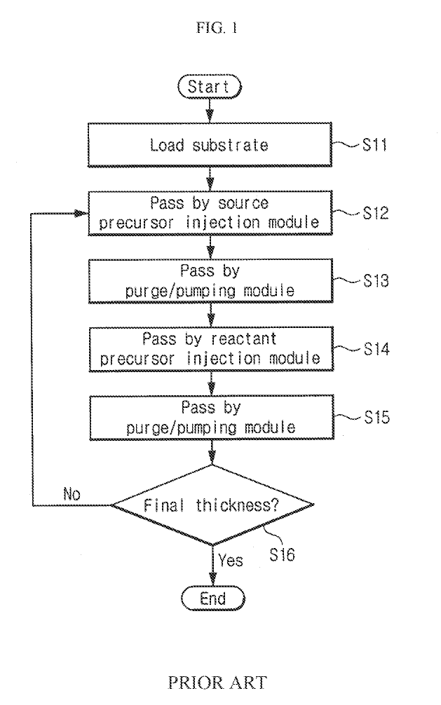

### DETAILED DESCRIPTION

Embodiments are described herein with reference to the accompanying drawings. Principles disclosed herein may, however, be embodied in many different forms and should not be construed as being limited to the embodiments set forth herein. In the description, details of well-known features and techniques may be omitted to avoid unnecessarily obscuring the features of the embodiments.

The terminology used herein is for the purpose of describing particular exemplary embodiments only and is not intended to be limiting of this disclosure. As used herein, the singular forms “a”, “an” and “the” are intended to include the plural forms as well, unless the context clearly indicates otherwise. Furthermore, the use of the terms a, an, etc. does not denote a limitation of quantity, but rather denotes the presence of at least one of the referenced item. The use of the terms “first”, “second”, and the like does not imply any particular order, but they are included to identify individual elements. Moreover, the use of the terms first, second, etc. does not denote any order or importance, but rather the terms first, second, etc. are used to distinguish one element from another. It will be further understood that the terms “comprises” and/or “comprising”, or “includes” and/or “including” when used in this specification, specify the presence of stated features, regions, integers, steps, operations, elements, and/or components, but do not preclude the presence or addition of at least one other features, regions, integers, steps, operations, elements, components, and/or groups thereof.

In the drawings, like reference numerals in the drawings denote like elements. The shape, size and regions, and the like, of the drawing may be exaggerated for clarity.

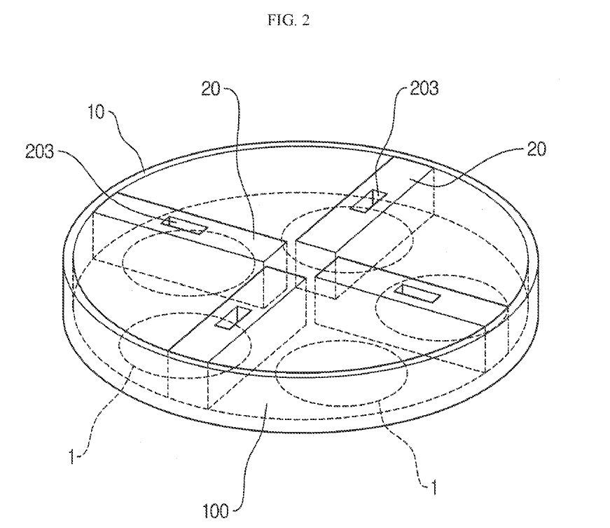

FIG. 2 is a schematic perspective view of a vapor deposition reactor according to an embodiment. The vapor deposition reactor may include, among others, at least one reaction module 20. The at least one reaction module is positioned in a chamber 10. Inside the chamber 10, at least one substrate 1 is loaded onto a support 100. The interior of the chamber 10 may be in a vacuum state. If needed to lower the base vacuum level of the chamber 10 to 10⁻³ Torr or lower to form a thin film (e.g., e.g. metal film) susceptible to residual oxygen, a vacuum pump such as a turbo-molecular pump (TMP) may be equipped in the chamber 10. Alternatively, the chamber 10 may be filled with a material.

The temperature of the substrate 1 and the atmosphere in the chamber 10 may affect the reaction. Hence, a heating apparatus (not shown) may be provided to control the temperature inside the chamber 10. When the heating apparatus is disposed below the chamber 10 to heat the substrate 1 indirectly, the space used for deposition is separated from the heating apparatus by the chamber 10, the support 100, etc. The heating apparatus may be purged by injecting an inert gas such as Ar such that materials used for deposition does not flow into the heating apparatus. The pressure of the injected purge gas may be controlled to be not lower than that of the space used for deposition so that the purge gas does not deteriorate deposition properties.

Although the chamber 10 illustrated in FIG. 2 has a cylindrical shape, this is merely illustrative. The chamber 10 may have any other arbitrary shape as long as the chamber 10 can accommodate the substrate 1 and the reaction module 20. The shape of the substrate 1 is also not limited to the disc shape illustrated in FIG. 2, but may be any arbitrary shape.

The at least one reaction module 20 may be fixed inside the chamber 10 but the support 100 holding the substrate 1 may rotate. The rotating speed of the support 100 may be constant. Alternatively, the rotating speed of the support 100 may be controlled using a computing device to vary the rotating speed depending on positions. As the support 100 rotates, the substrate 1 may pass below the reaction module 20. In another embodiment, the substrate 1 may be fixed and the reaction module 20 may be rotated to generate a relative motion between the substrate 1 and the reaction module 20.

In the vapor deposition reactor of the above embodiment, the relative motion between the substrate 1 and the reaction module 20 is rotation. In other embodiments, the relative motion between the substrate 1 and the reaction module 20 may be a linear or reciprocal motion.

While the substrate 1 passes below the reaction module 20, the substrate 1 may be separated from the bottom surface of the reaction module 20 by a predetermined distance to maintain a non-contact state. The substrate 1 passing below the reaction module 20 may be exposed to the material injected from the reaction module 20. As a result, an adsorption layer is formed on the substrate 1.

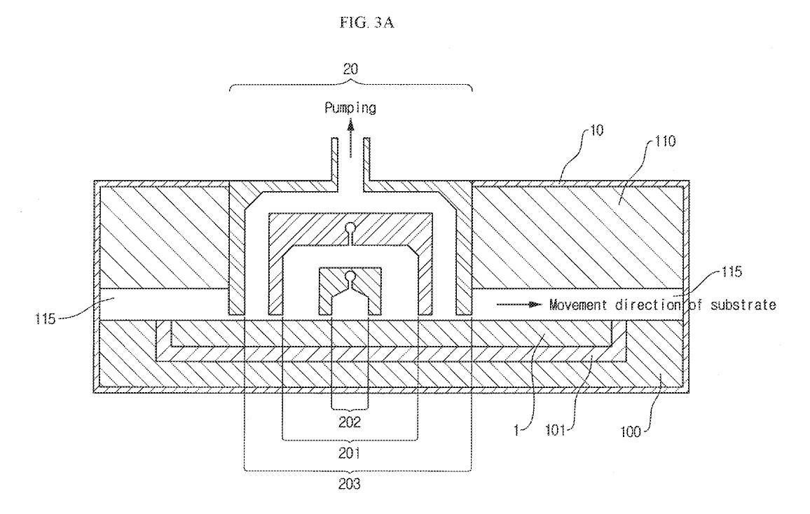

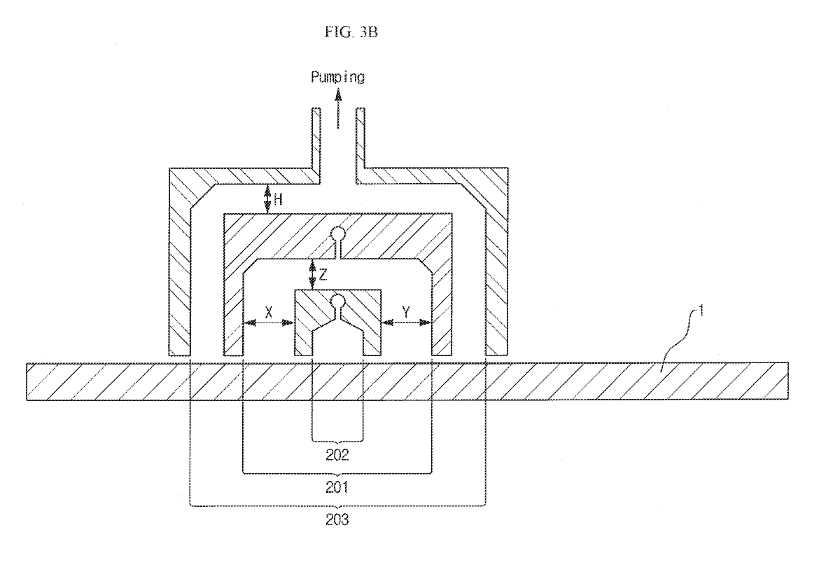

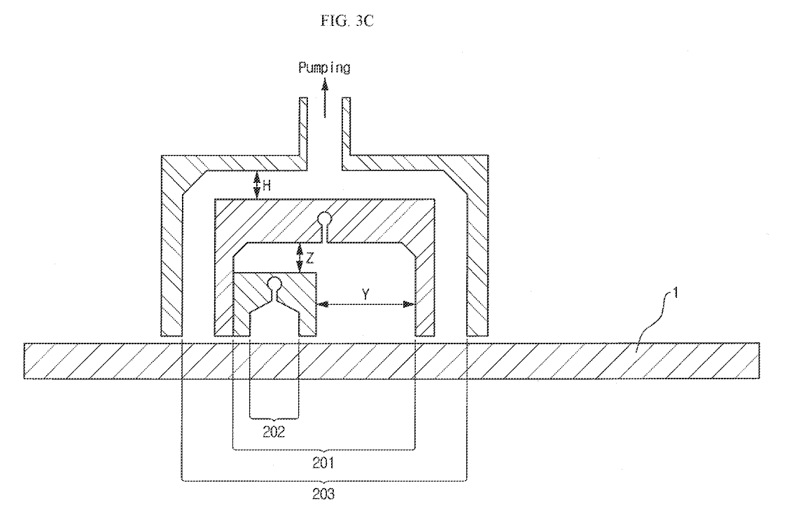

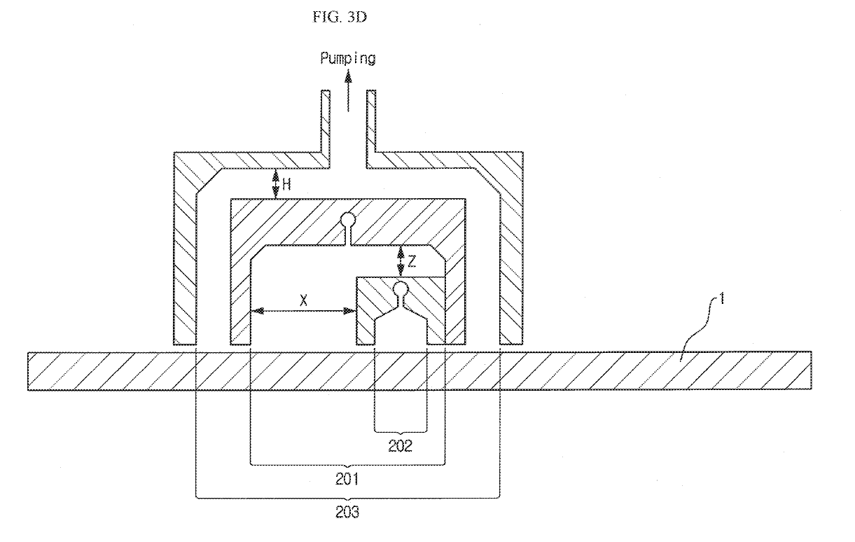

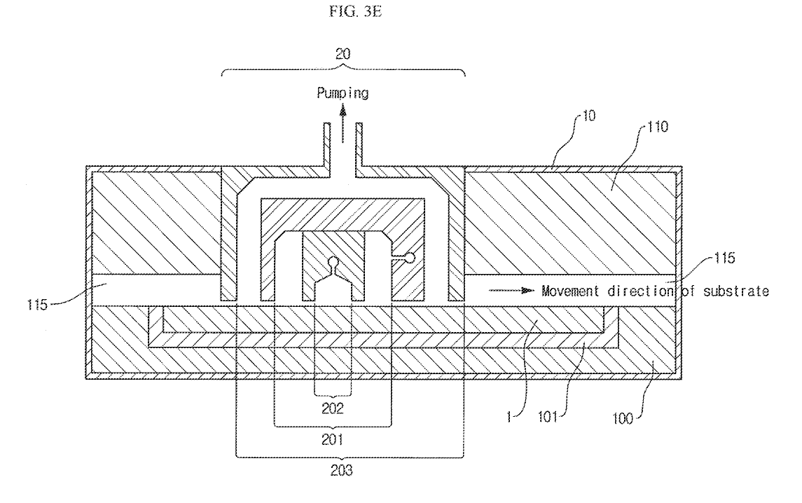

The material injected from each reaction module 20 may be the same or different. For example, by injecting a reactant precursor using one reaction module 20 and injecting a source precursor using another reaction module 20, an atomic layer may be formed on the substrate 1 as the substrate 1 passing the two reaction modules 20, as described below in detail with reference to FIGS. 3A and 3B.

In one embodiment, depending on the type of the thin film desired, the reaction module 20 may include a plasma generator, ultrahigh frequency wave generator or UV generator. These energy sources may be used in combination with the same process or these energy sources may be used sequentially in different processes to form a thin film, as described below in detail.

FIG. 3A is a cross-sectional view of a vapor deposition reactor according to one embodiment. FIG. 3B is a partially enlarged view of a portion where a substrate 1 and a reaction module 20 are adjacent to each other in the vapor deposition reactor of FIG. 3A. The substrate 1 fixed onto a susceptor 101 of a support 100 moves from the left to the right. That is, the substrate 1 passes the lower portion of the reaction module 20 from the left to the right. The substrate 1 and the reaction module 20 may be spaced apart from each other and maintain a non-contact state. For example, the distance between the substrate 1 and the reaction module may be about 1 mm to about several millimeters. Before the substrate 1 passes the lower portion the reaction module 20, impurities or adsorbates may be formed on the surface of the substrate 1 due to the presence of atmosphere in a chamber 10.

In one embodiment, the chamber 10 includes a channel 115 at a region adjacent to the substrate 1. In this case, the remaining region of the chamber 10 excluding the channel 115 may be filled with a filler 110. The filler 110 may be the same as the material constituting the outer wall of the chamber 10. Such a configuration is economically advantageous because the amount of the material needed to fill the chamber 10 may be reduced.

The reaction module 20 may include a first injection unit 201, and a second injection unit 202 positioned within the first injection unit 201. Further, the first and second injection units 201, 202 may be positioned within an exhaust unit 203. The size of the reaction module 20 and the size of each of the first injection unit 201, second injection unit 202 and exhaust unit 203 may be set adequately depending on the materials or the types of thin films to be formed. The exhaust unit 203 and the first injection unit 201 may be spaced apart from each other in a direction perpendicular to the direction of movement of the substrate 1 by a distance H. Further, the first injection unit 201 and the second injection unit 202 may be spaced apart from each other in a direction perpendicular to the direction of movement of the substrate 1 by a distance Z. In addition, the first and second injection units 201, 202 may be spaced apart from each other in the direction of movement of the substrate 1 and in the opposite direction by distances X, Y, respectively. The distances H, X, Y, Z may be set adequately depending on the materials or the types of thin films to be formed.

When all or part of the substrate 1 from the left side of the figure is positioned below the exhaust unit 203 of the reaction module 20, the impurity or adsorbate is discharged out of the chamber 10 by the exhaust unit 203. When the substrate 1 moves further to the right and the corresponding region is positioned below the first injection unit 201, the first injection unit 201 injects a first material to the substrate 1. For example, the first material is a purge gas. By injecting the purge gas onto the substrate 1, the molecules physically adsorbed in the surface of the substrate 1 may be removed. As a result, only a chemical adsorption layer formed by preceding processes remains on the substrate 1. Alternatively, if there was no preceding process, the substrate 1 may be void of an adsorption layer. The purge gas may be an inert gas. For example, the purge gas may include N₂ gas, Ar gas, He gas, or other suitable material. Further, the purge gas may include a combination of two or more of above materials. The first material may include a source precursor or a reactant precursor for forming an atomic layer.

When the substrate 1 moves further to the right and all or part of the substrate 1 is positioned below the second injection unit 202, the injection unit 202 injects a second material to the substrate 1. The second material may be a material for forming a thin film on the substrate 1. For example, the second material includes a source precursor or a reactant precursor for forming an atomic layer.

The reactant precursor may be a material for obtaining metal, oxide, nitride, carbide or semiconductor material from a chemical source. For example, the first material may include H₂O, H₂O₂, O₂, N₂O, O₃, O* radical, NH₃, NH₂—NH₂, N₂, N* radical, organic carbon compounds such as CH₄, C₂H₆, etc., H₂, H* radical, or other suitable material. The first material may include a combination of two or more of above materials.

Further, the source precursor may be a material capable of forming a thin film on the substrate 1 by reaction and/or substitution with the reactant precursor. A variety of materials may be used as the source precursor depending on the thin film to be formed. For example, in case the thin film is made of a semiconductor, the source precursor may be group IV compounds, group III-V compounds, group II-VI compounds, or the like. In case the thin film is made of a metal, the source precursor may be Ni-based compounds, Co-based compounds, Al-based compounds, Ti-based compounds, Hf-based compounds, Zr-based compounds, Ta-based compounds, Mo-based compounds, W-based compounds, or compounds including above materials and Si. In case the thin film is made of a dielectric or a conductive dielectric, the source precursor may be Ni-based compounds, Zn-based compounds, Cu-based compounds, Co-based compounds, Al-based compounds, Si-based compounds, Hf-based compounds, Ti-based compounds, Zr-based compounds, Ta-based compounds, or the like. The source precursor may include a combination of two or more of the above materials.

For example, Si-based compounds used as the second material may include SiH₄, SiH₂Cl₂, or the like. Ti-based compounds used as the second material may include TiCl₄, or the like. Al-based compounds used as the second material may include trimethylaluminum (TMA), or the like. Hf-based compounds used as the second material may include tetrakis-ethylmethylaminohafnium (TEMAHf), or the like. Zr-based compounds used as the second material may include tetrakis-ethylmethylaminozirconium (TEMAZr), or the like. The kind of the second materials is not limited to these materials, and other materials not listed herein may also be used depending on the kind of the final thin film.

The reactant precursor may be in the form of plasma of the above material, or may be supplied along with light such as UV light. Even when the reactant precursor is decomposed by applying plasma, radical, or photon, it is not likely that the byproduct remains in the final thin film or the property of the thin film is deteriorated or degraded. If the reactant precursor is activated by such energy, a sufficient adsorption of molecules may be attained even when Si-based compounds or TiCl₄, which do not readily form a thin film, are used as the source precursor. As a result, the rate of thin film deposition may be increased and the surface treatment or interface treatment of the substrate 1 may be facilitated.

The first and second injection units 201, 202 may be a rectangular showerhead type injector. Alternatively, since inner portions and outer portions of the substrate 1 have difference angular velocities when the support 100 rotates, the first and second injection units 201, 202 may be a pie-shaped injector having the shape to account for the different angular velocities in different portions of the substrate. In this way, the uniformity of the thin film may be improved.

When the substrate 1 moves further to the right and passes the second injection unit 202, the substrate 1 is positioned again below the first injection unit 201. The first injection unit 201 may inject the first material such as a purge gas onto the substrate 1. A physical adsorption layer and a chemical adsorption layer of the second material may be formed on the substrate 1 that has passed the second injection unit 202. The physical adsorption layer may be separated from the substrate 1 by the purge gas injected from the first injection unit 201.

When the substrate 1 moves further to the right, the substrate 1 becomes positioned below the exhaust unit 203. At this location, the purge gas and the physical adsorption layer of the second material are removed by pumping the purge gas and the physical absorption layer out of the chamber 10. As a result, only the chemical adsorption layer of the second material remains on the surface of the substrate 1 after passing the reaction module 20.

As the substrate 1 passes one reaction module 20, the following three stages are preformed sequentially on the substrate 1: (i) injection of the first material, (ii) injection of the second material (reactant precursor or source precursor), and (iii) injection of the first material. Stages of pumping by the exhaust unit 203 may be added before and/or after the three stages. By changing the position of the second injection unit 202 (or separating the second injection unit 202 from the first injection unit 201), the time interval during which the substrate 1 passes the distance Y between the first injection unit 201 and the second injection unit 202 is changed, and thus, the time interval for injecting the first material is changed accordingly. Therefore, using precursors having different adsorption properties is advantageous in optimizing the purge amount and purge time. As a result, only the chemical adsorption layer of the reactant precursor or the source precursor remains on the surface of the substrate 1 after passing the reaction module 20.

In one embodiment wherein the distance Y between the first injection unit 201 and the second injection unit 202 is decreased, a portion of the physical adsorption layer of the reactant precursor or the source precursor remains on the substrate 1 because the purge time of the reactant precursor or the source precursor may be insufficient. Compared to depositing a thin film by a pure atomic layer, the remaining physical adsorption layer may increase the rate of deposition of the thin film.

The substrate 1 with the chemical adsorption layer of the reactant precursor or the source precursor may pass another reaction module 20 to form a thin film on the substrate 1. For example, a substrate 1 with a chemical adsorption layer of the reactant precursor formed by passing one reaction module 20 may pass another reaction module 20 injecting the source precursor. As a result, an atomic layer may be formed on the substrate 1 by substitution and/or reaction of the reactant precursor with the source precursor. On the contrary, a chemical adsorption layer of the source precursor may be first formed on the substrate 1 by one reaction module 20, and then the reactant precursor may be injected by another reaction module 20 to form an atomic layer.

FIGS. 3C and 3D are cross-sectional views of a reaction module of a vapor deposition reactor, according to other embodiments. The distance X (see FIG. 3B) between the first injection unit 201 and the second injection unit 202 in the direction opposite to the movement direction of the substrate 1 may be 0. That is, the second injection unit 201 is in contact with the inner wall of the first injection unit 201 as illustrated in FIG. 3C. Alternatively, the second injection unit 202 is in contact with an inner wall of the first injection unit 201 at the opposite side, as illustrated in FIG. 3D. As illustrated in FIGS. 3C and 3D, parameters for performing deposition may be varied by controlling the distances X, Y, Z between the first and second injection units 201, 202 in each direction.

FIG. 3E is a cross-sectional view of a vapor deposition reactor, according to another embodiment. In this embodiment, the purge gas is sprayed from a side wall of the first injection unit 201. As the sprayed purge gas passes the substrate 1, a portion of the precursors adsorbed on the substrate 1 is desorbed from the substrate 1. The desorbed precursors are then discharged by the exhaust unit 203. The second injection unit 202 may be in contact with an upper portion of the inner surface of the first injection unit 201. The purge gas is sprayed from a side wall of the first injection unit 201. Thus, the purge gas is sprayed in a direction opposite to the moving direction of the substrate 1 and is discharged by the exhaust unit 203. Alternatively, in another embodiment, the purge gas is sprayed from a side wall of the first injection unit 201 opposite to the side wall as illustrated in FIG. 3E.

A detailed description on the operation of the vapor deposition reactor illustrated in FIGS. 3C to 3E is omitted herein for the purpose of brevity.

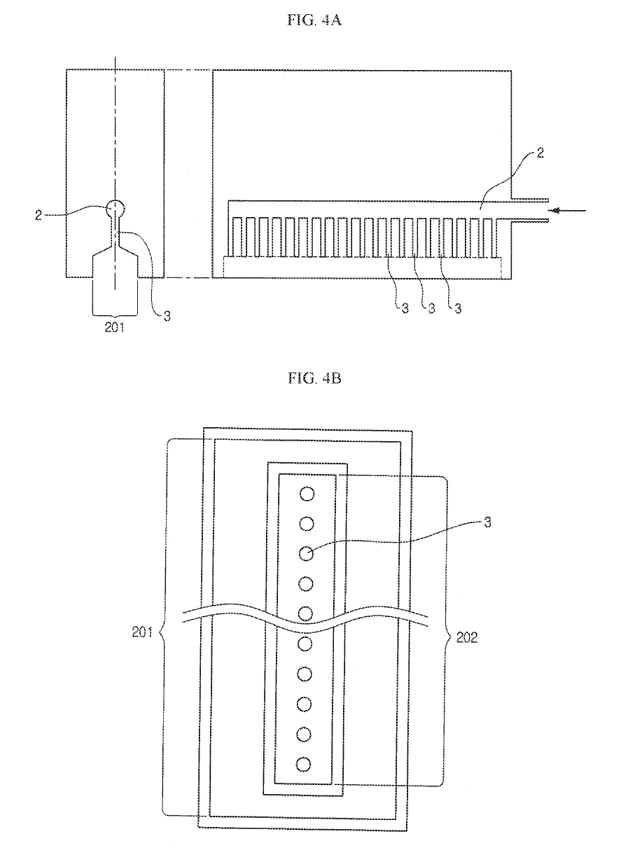

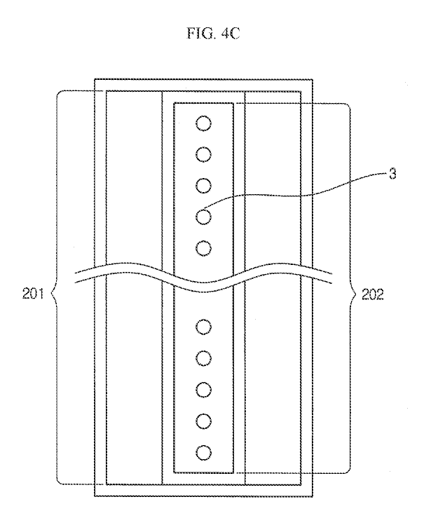

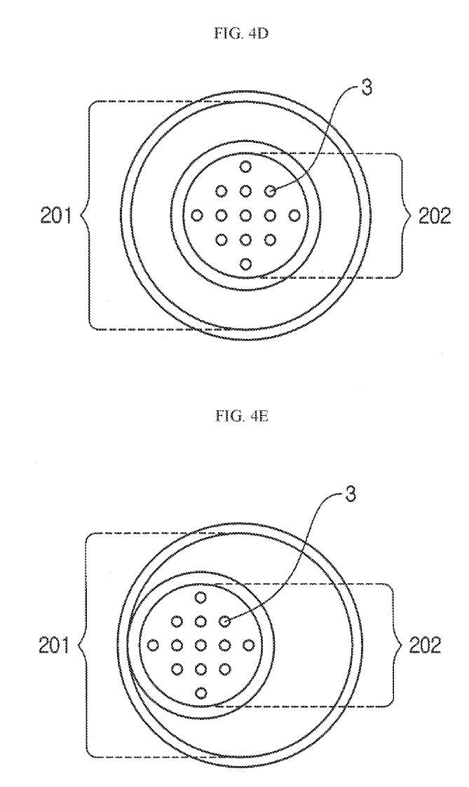

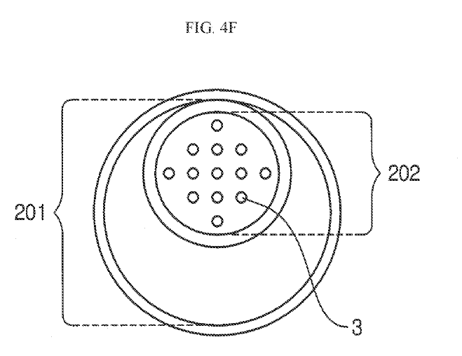

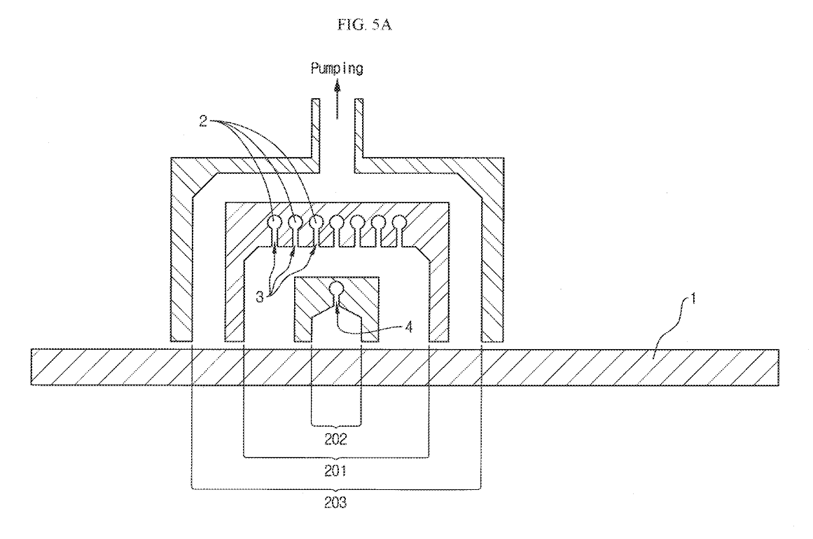

FIG. 4A is a side cross-sectional view of a first injection unit 201 of a vapor deposition reactor, according to one embodiment. As illustrated in FIG. 4A, the first injection unit 201 includes a pipe-shaped channel 2 through which the first material is injected and transferred. The first material transferred through the channel 2 is injected onto the substrate below through at least one hole 3 formed in the channel 2. Each hole 3 may have the same or different size. Although an example configuration of the first injection unit 201 is shown in FIG. 4A, the configuration of the second injection unit 202 may also be the same.

FIG. 4B is a bottom view of a reaction module of a vapor deposition reactor, according to one embodiment. As illustrated, the second injection unit 202 may be placed in the first injection unit 201 spaced apart from the first injection unit 201. The second material may be injected through at least one hole 3 of the second injection unit 202. In FIG. 4B, the hole of the first injection unit 201 is not illustrated it is occluded by the second injection unit 202.

FIG. 4C is a bottom view of a reaction module of a vapor deposition reactor, according to another embodiment. As illustrated, the second injection unit 202 is positioned in the first injection unit 201 in contact with at least one inner wall of the first injection unit 201. However, the second injection unit 202 should be spaced apart from at least one of the inner walls of the first injection unit 201 because the first material is injected onto the substrate by the first injection unit 201.

FIG. 4D is a bottom view of a reaction module of a vapor deposition reactor, according to another embodiment. As illustrated in FIG. 4D, the first injection unit 201 and the second injection unit 202 have circular cross-sections. For example, the first injection unit 201 and the second injection unit 202 may have the shape of a circular cylinder. The second injection unit 202 may be placed in the first injection unit 201 spaced apart from the first injection unit 201. The second material may be injected through at least one hole 3 of the second injection unit 202. In FIG. 4D, the hole of the first injection unit 201 is not illustrated because the hole is occluded by the second injection unit 202.

FIGS. 4E and 4F are bottom views of a reaction module of a vapor deposition reactor, according to other embodiments. Referring to FIG. 4E, the second injection unit 202 may be positioned in the first injection unit 201 while in contact with an inner wall of the first injection unit 201. Referring to FIG. 4F, the second injection unit 202 may be in contact with the inner wall of the first injection unit 201 from a direction different from that of FIG. 4E.

The cross-sections of the reaction module shown in FIGS. 4B to 4F are merely illustrative. The reaction module may have a cross-section of different shapes.

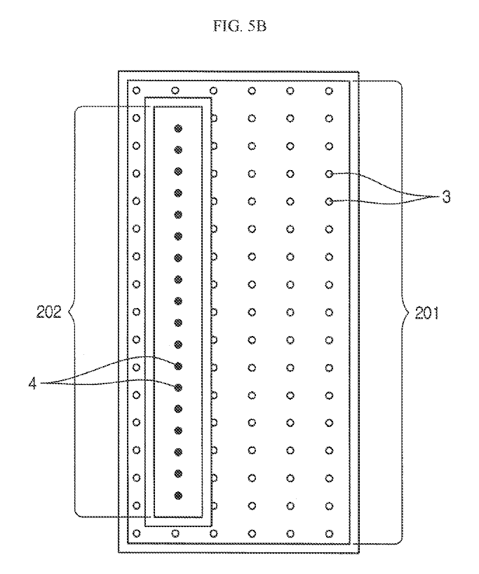

FIG. 5A is a cross-sectional view of a reaction module of a deposition reactor, according to another embodiment. The reaction module may include a first injection unit 201 and a second injection unit 202. The first injection unit 201 may include a plurality of channels 2 and holes 3 respectively connected to each of the channels 2. By providing the plurality of channels 2 through which the first material is transferred, the first material is uniformly injected over a large area of the substrate 1.

FIG. 5B is a bottom view of the reaction module of FIG. 5A, according to one embodiment. As illustrated, a plurality of holes 3 may be arranged on the bottom surface of the first injection unit 201 with constant intervals to uniformly inject the first material onto the substrate. In FIG. 5B, the holes 4 are used for injecting the second material by the second injection unit 202.

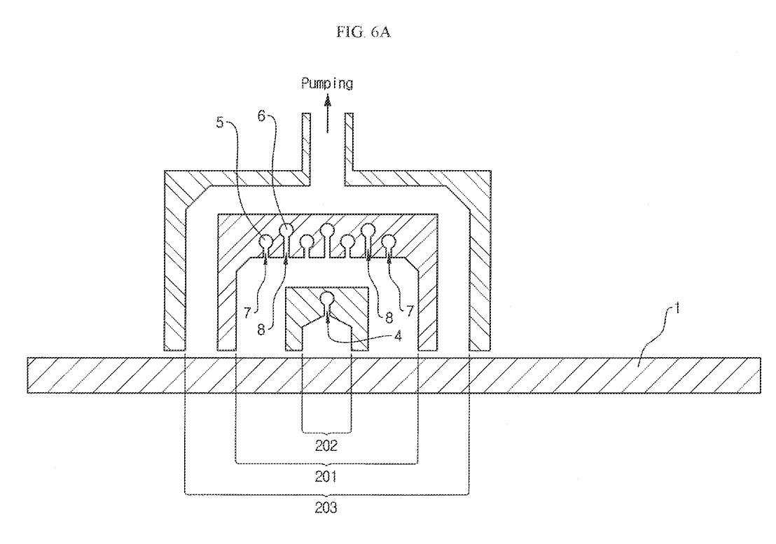

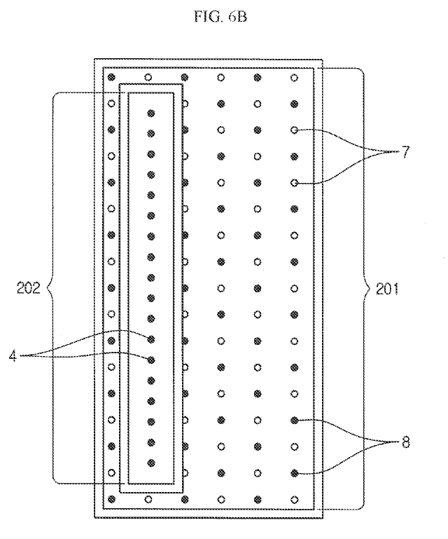

FIG. 6A is a cross-sectional view of a reaction module of a vapor deposition reactor, according to another embodiment. The reaction module includes a first injection unit 201 and a second injection unit 202. The first injection unit 201 may have at least one first channel 5 and at least one second channel 6. Different first materials may be injected through the first channel 5 and the second channel 6. Further, the first channel 5 and the second channel 6 may have a first hole 7 and a second hole 8, respectively.

FIG. 6B is a bottom view of the reaction module of FIG. 6B, according to one embodiment. As illustrated, the first hole 7 and the second hole 8 is arranged to alternate on the bottom surface of the first injection unit 201. With such a configuration, two different first materials can be uniformly injected onto the substrate. In the embodiment of FIGS. 6A and 6B, two sets of channels 5, 6 and two sets of holes 7, 8 are provided to inject two kinds of first materials. However, more sets of channels and holes may be provided depending on the types of the injected materials.

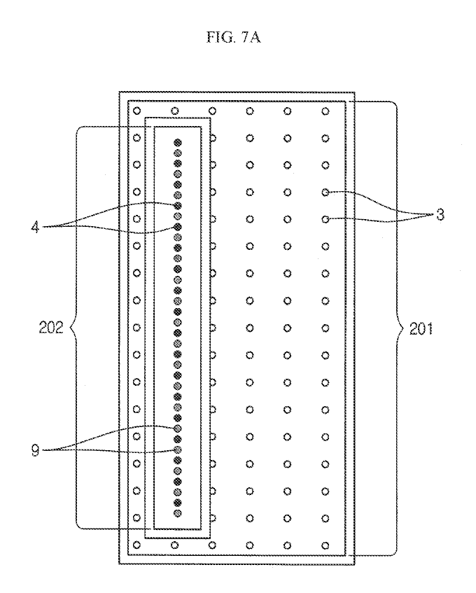

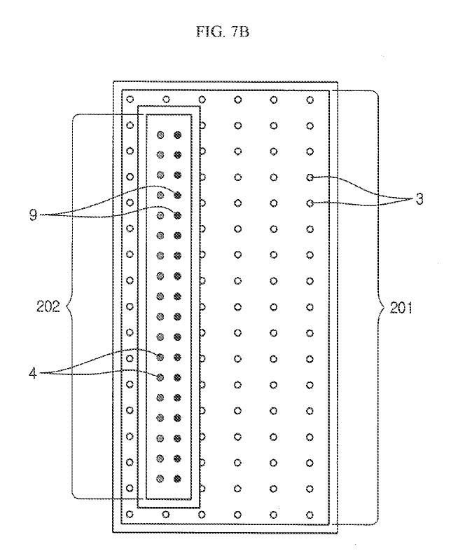

FIG. 7A is a bottom view of a reaction module of a vapor deposition reactor, according to one embodiment. A reaction module may include a first injection unit 201 and a second injection unit 202. The second injection unit 202 may have a first hole 4 and a second hole 9 through which different second materials are injected. The first and second holes 4, 9 may be connected to different channels, as described above in detail with reference to FIG. 6A.

FIG. 7B is a bottom view of a reaction module of a vapor deposition reactor, according to another embodiment. The second injection unit 202 may have a first hole 4 and a second hole 9 through which different second materials are injected. The first and second holes 4, 9 in FIG. 7A are alternate in a single row. The first and second holes 4, 9 in FIG. 7B are arranged separately in two rows parallel to each other.

With the configuration illustrated in FIG. 7A or 7B, a plurality of different second materials may be injected onto the substrate. For example, a source precursor may be injected onto the substrate through the first hole 4, and a reactant precursor may be injected onto the substrate through the second hole 9. Because both the source precursor and the reactant precursor are injected to the substrate when passing one reaction module, an atomic layer may be formed on the substrate using one reaction module.

The arrangement of the first hole 4 and the second hole 9 in FIGS. 7A and 7B is merely illustrative and different arrangement may be used in other embodiments. Further, although two sets of holes 4, 9 are provided to inject two types of second materials in the embodiment of FIGS. 7A and 7B, additional sets of holes may be provided depending on the type of the injected materials.

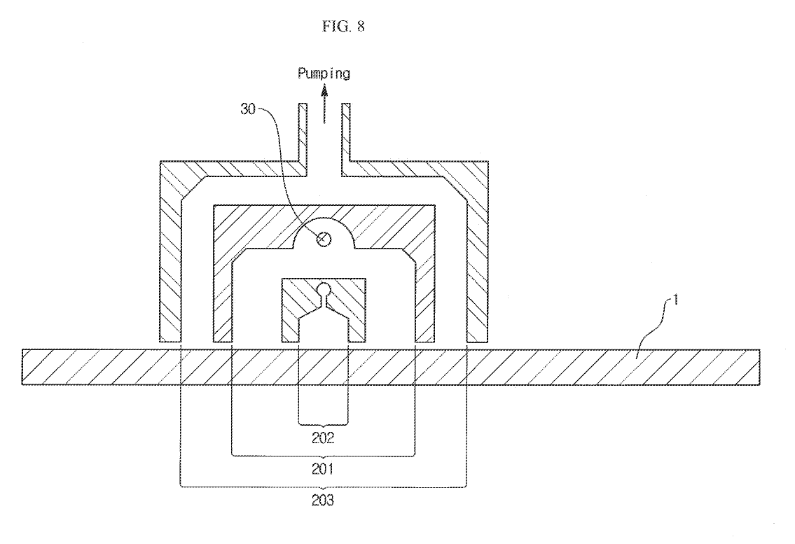

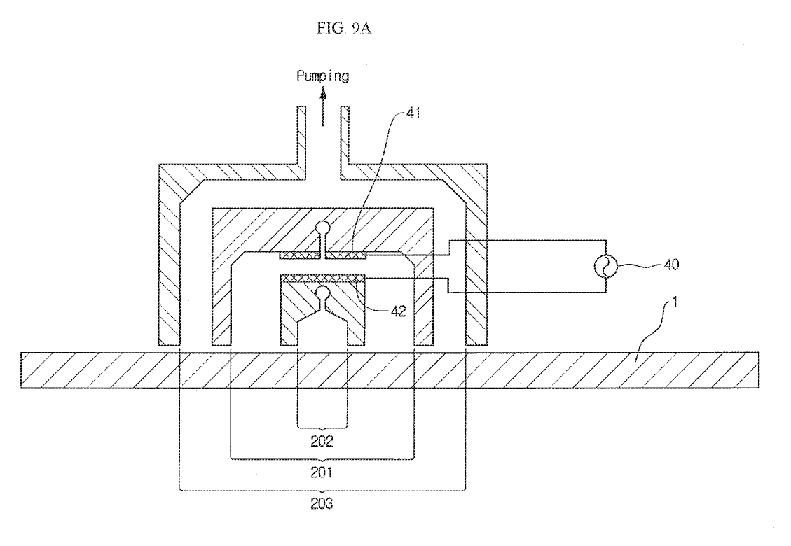

FIG. 8 is a cross-sectional view of a reaction module of a vapor deposition reactor, according to another embodiment. A reaction module may include a first injection unit 201, a second injection unit 202, and an exhaust unit 203. The first injection unit 201 may have a plasma generator 30 for radical-assisted atomic layer deposition (ALD). The first material may be applied to the substrate 1 in the form of plasma. The plasma generator 30 may be well-known apparatuses. For example, the plasma generator 30 may apply voltage between coaxial electrodes facing each other to generate plasma of the reaction gas between the electrodes.

The first injection unit 201 may be used to excite (or decompose) an inorganic source precursor (which is difficult to attain in ALD) with plasma and form an atomic layer. That is, after inducing a primary reaction (or decomposition) of the source precursor by plasma energy, the source precursor may react with a reactant precursor. For example, by injecting an inorganic metal source such as TiCl₄ or SiH₄ to the substrate 1 as a source precursor by the first injection unit 201 and injecting NH₃ as a reactant precursor by the second injection unit 202, TiN or SiN thin film may be formed on the substrate 1. However, the resultant thin film may include residual Cl or H, as well as NH₄Cl formed from the reaction of NH₃ and Cl.

However, when the first injection unit 201 injects TiCl₄ in the form of plasma as described above, TiN thin film may be deposited at low temperature because Ti and Cl atoms are decomposed and Ti atoms are adsorbed at low temperature. Further, by injecting the source precursor mixed with TiCl₄ and H₂ by the first injection unit 201, Ti atomic layer or a similar adsorption layer may be obtained by the plasma energy. Therefore, incubation or decreased deposition rate may be improved due to less adsorption. When forming gas (N₂+H₂) is used as a reactant precursor in the second injection unit 202, Ti thin film may be obtained on the substrate 1. Si thin film may also be obtained in a similar way.

Although the plasma generator 30 is provided in the first injection unit 201 of the above embodiments, a UV or ultrahigh frequency wave generator may be provided in other embodiments to attain a similar effect.

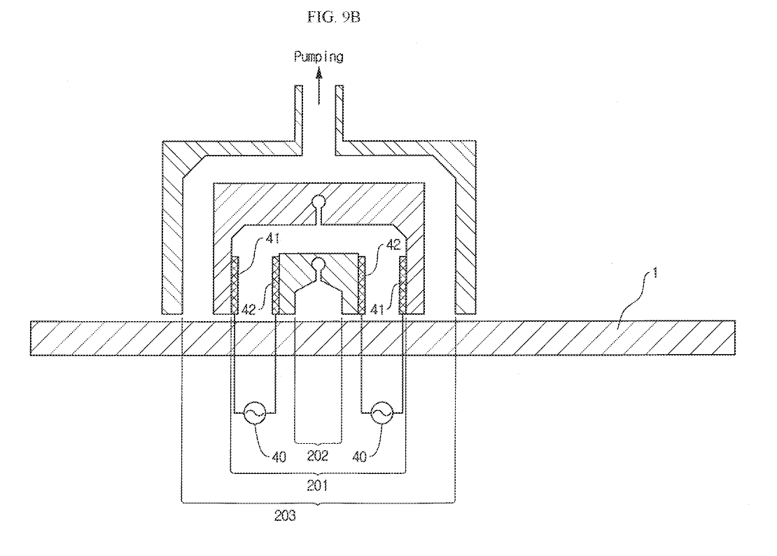

FIG. 9A is a cross-sectional view of a reaction module of a vapor deposition reactor according to another exemplary embodiment. Referring to FIG. 9A, the reaction module may include, among others, a first injection unit 201, a second injection unit 202, a first electrode 41 and a second electrode 42. The first and second electrodes 41, 42 generate plasma between the first injection unit 201 and the second injection unit 202.

The first electrode 41 may be in contact with the inner wall of the first injection unit 201, and the second electrode 42 may be in contact with the inner wall of the second injection unit 202. The first and second electrodes 41, 42 are spaced apart from each other with a predetermined interval. In case the first electrode 41 is adjacent to a channel of the first injection unit 201, the first electrode 41 may include a hole for injecting a first material. The first injection unit 201 may also be configured to inject a reaction gas for generating plasma in addition to the first material.

Between the first and second electrodes 41, 42, an AC power or a pulsed power may be applied by a power supply 40. Plasma may be generated from the reaction gas by the power applied between the first and second electrodes 41, 42. Radical activated by the plasma may be provided to a substrate 1 along with the first material, as described above in detail with reference to FIG. 8.

FIG. 9B is a cross-sectional view of a reaction module of a vapor deposition reactor, according to another embodiment. First and second electrodes 41, 42 are arranged to apply an electric field in a direction parallel to the moving direction of the substrate 1. The first and second electrodes 41, 42 may be provided in multiple pairs. Between each pair of the first and second electrodes 41, 42, voltage may be applied by a power supply 40.

Using such a reaction module, a radical having a very short lifespan such as hydrogen radical or nitrogen radical may be applied to the substrate 1 because plasma is generated directly above the substrate 1. Further, damage of the substrate 1 attributable to the plasma may be minimized because the plasma is sprayed in a direction parallel to the surface of the substrate 1.

In conventional reactors, a single atomic layer had to be formed by increasing the number of cycles when using a source precursor (e.g., TiCl₄, SiH₄, etc.) that does not exhibit the self-limiting phenomenon (i.e. source precursors do not exhibit saturation during chemical adsorption). However, when the vapor deposition reactor according to embodiments is used, the adsorption of the source precursor is sufficiently induced due to the surface activation by the plasma. As a result, no additional nucleation process is required and atomic layer can be formed without the incubation phenomenon.

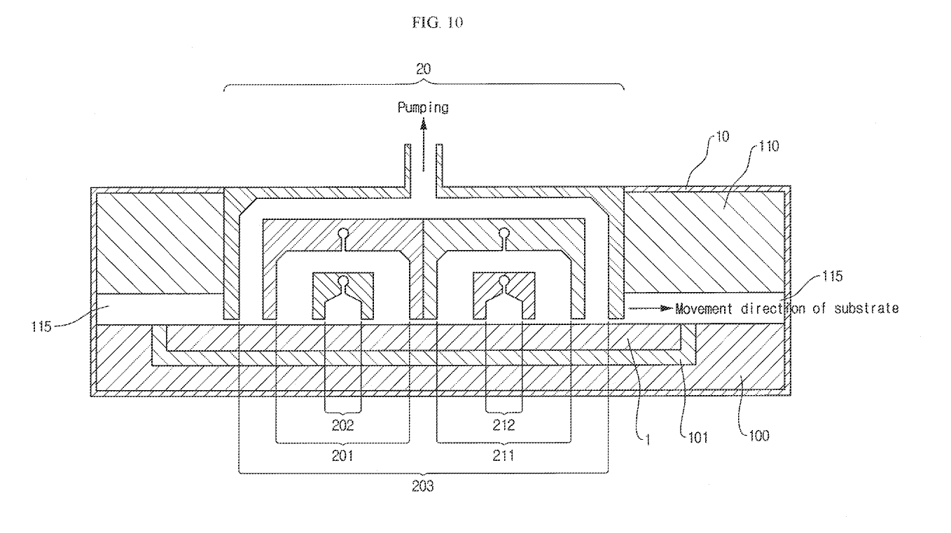

FIG. 10 is a cross-sectional view of a reaction module of a vapor deposition reactor, according to another embodiment. The reaction module 20 of the vapor deposition reactor may include, among others, a plurality of first injection units 201, 211 and a plurality of second injection units 202, 212 placed within each of the first injection units 201, 211, respectively. The plurality of first injection units 201, 211 and the second injection units 202, 212 may be placed within one exhaust unit 203.

An illustrative process of forming a thin film using the vapor deposition reactor according to embodiments is described herein. When a substrate 1 is moved below the reaction module 20 from the left, an impurity or adsorbate on the substrate 1 may be removed by the exhaust unit 203. When the substrate 1 moves further to the right and is placed below the first injection unit 201, a first material is injected onto the substrate 1 by the first injection unit 201. The first material may be a purge gas.

When the substrate 1 moves further to the right and is positioned below the second injection unit 202, a second material is injected onto the substrate 1 by the second injection unit 202. For example, the second injection unit 202 injects a reactant precursor onto the substrate 1. After passing the second injection unit 202, the substrate 1 sequentially passes the first injection unit 201 and then another first injection unit 211. During this process, a first material may again be injected onto the substrate 1.

When the substrate moves further to the right and is positioned below the second injection unit 212, another second material is injected to the substrate 1 by the second injection unit 212. For example, the second injection unit 212 injects a source precursor onto the substrate 1. Then, a thin film is formed on the substrate 1 by substitution and/or reaction of a chemical adsorption layer of the reactant precursor (injected by the second injection unit 202) with the source precursor injected by the second injection unit 212. As the substrate 1 moves further to the right, the substrate 1 again passes the first injection unit 211 and the exhaust unit 203, and then completely leaves from the reach of the reaction module 20.

As the substrate 1 passes one reaction module 20, the following five stages are performed sequentially on the substrate 1: (i) injection of the first material, (ii) injection of the second material (reactant precursor), (iii) injection of the first material, (iv) injection of the second material (source precursor), and (v) injection of the first material. As a result, a thin film may be formed on the substrate 1. Further, the stages of pumping by the exhaust unit 203 may be added before and/or after the five stages.

The first injection units 201, 211 and the second injection units 211, 212 illustrated in FIG. 10 may be configured according to any of the embodiments described above with reference to FIGS. 2 to 9. That is, at least one of the first injection units 201, 211 may include a plasma generator, and at least one electrode for generation of plasma may be included between each pairs 201-211, 202-212 of first injection unit and second injection unit. Further, at least one of the first injection units 201, 211 and the second injection units 211, 212 has a plurality of channels and holes. The configuration of a first injection unit 201 and another first injection unit 211 may be different. Likewise, the configuration of a second injection unit 211 and another second injection unit 212 may be different.

Using the vapor deposition reactor according to embodiments, a plurality of different materials may be injected onto a substrate by means of multiple injection units. Accordingly, a thin film may be formed by injecting a source precursor or a reactant precursor onto a substrate without exposing the substrate to the atmosphere in a chamber. The vapor deposition reactor may be used for ALD.

Although the present invention has been described above with respect to several embodiments, various modifications can be made within the scope of the present invention. Accordingly, the disclosure of the present invention is intended to be illustrative, but not limiting, of the scope of the invention, which is set forth in the following claims.

What is claimed is:

1. A vapor deposition reactor comprising a first reaction module, the first reaction module comprising:
a first injection unit for injecting a first material onto a substrate; and
at least one second injection unit within the first injection unit for injecting a second material to the substrate, the substrate passing the reaction module by a relative motion between the substrate and the reaction module.

2. The vapor deposition reactor according to claim 1, wherein the reaction module further comprises an exhaust unit for discharging a material outside the vapor deposition reactor, and wherein the first injection unit and the second injection unit are placed within the exhaust unit.

3. The vapor deposition reactor according to claim 1, further comprising a chamber for receiving the reaction module.

4. The vapor deposition reactor according to claim 1, wherein the first material comprises a purge gas.

5. The vapor deposition reactor according to claim 4, wherein the purge gas is selected from a group consisting of N₂, Ar, He and a combination thereof.

6. The vapor deposition reactor according to claim 1, further comprising a second reaction module, and wherein the second injection units of the first and the second reaction modules inject different second materials onto the substrate.

7. The vapor deposition reactor according to claim 6, wherein the second materials form a thin film on the substrate by reaction or substitution.

8. The vapor deposition reactor according to claim 1, wherein the at least one second injection unit comprises a plurality of the second injection units, each second injection unit injecting different second materials onto the substrate.

9. The vapor deposition reactor according to claim 8, wherein the second materials form a thin film on the substrate by reaction or substitution.

10. The vapor deposition reactor according to claim 1, wherein the distance between the first injection unit and the at least one second injection unit is determined based on deposition properties of a thin film to be formed by the vapor deposition reactor.

11. The vapor deposition reactor according to claim 1, wherein the second material comprises a reactant precursor or a source precursor.

12. The vapor deposition reactor according to claim 11, wherein the reactant precursor is selected from a group consisting of H₂O, H₂O₂, O₂, N₂O, O₃, O* radical, NH₃, NH₂—NH₂, N₂, N* radical, CH₄, C₂H₆, H₂, H* radical and a combination thereof.

13. The vapor deposition reactor according to claim 11, wherein the source precursor is selected from a group consisting of a group IV compound, a group III-V compound, a group II-VI compound, a Ni-based compound, a Co-based compound, a Cu-based compound, an Al-based compound, a Ti-based compound, a Hf-based compound, a Zr-based compound, a Ta-based compound, a Mo-based compound, a W-based compound, a Si-based compound, a Zn-based compound and a combination thereof.

14. The vapor deposition reactor according to claim 1, wherein the first injection unit comprises at least one of a plasma generator, an ultrahigh frequency wave generator and a UV generator.

15. The vapor deposition reactor according to claim 1, wherein the reaction module further comprises at least one electrode for generating plasma between the first injection unit and the second injection unit.

16. The vapor deposition reactor according to claim 15, wherein the at least one electrode is configured to apply an electric field in a direction parallel to moving direction of the substrate.

17. The vapor deposition reactor according to claim 1, wherein at least one channel in a shape of a linear pipe and at least one hole in each of the at least one channel are formed in the first injection unit and the second injection unit.

18. The vapor deposition reactor according to claim 17, wherein at least two channels are formed in the first injection unit and the second injection unit, each injecting different materials onto the substrate.
